(19) United States
(12) Patent Application Publication
(10) Pub. No.: US 2011/0271995 A1
(43) Pub. Date: Nov. 10, 2011

(54) Thermoelectric modules

(76) Inventors: Franz Wetzl, Mundelsheim (DE); Martin Rittner, Freiberg (DE); Matthias Leonhardt, Stuttgart (DE); Antje Winkelmann, Seeheim-Jugenheim (DE)

(21) Appl. No.: 13/066,985

(22) Filed: Apr. 29, 2011

(30) Foreign Application Priority Data
May 4, 2010 (DE) 10 2010 028 535.8

(51) Int. Cl. H01L 35/32; H01L 35/34

(52) U.S. Cl. 136/224; 136/201

(57) ABSTRACT

A thermoelectric module includes: thermoelectric semiconductor elements; printed metal conductors for interconnecting the semiconductor elements; and at least one base support for the printed conductors, the base support including a metal matrix composite.

### BACKGROUND OF THE INVENTION

1. Field of the Invention

The present invention relates to thermoelectric modules, in particular for use as thermoelectric generators.

2. Description of the Related Art

When integrated into an appropriate generator, thermoelectric modules make it possible to generate current by utilizing a temperature gradient in a system.

The basic structure of a known thermoelectric module (TEM) is outlined in FIG. 1. Printed conductors 102 of metal are situated on a ceramic base support 100. They are used for the circuit routing of a plurality of thermoelectric semiconductors of n-type 104 or p-type 106. Printed conductors 102 may, for example, be made of copper. Semiconductor elements or thermocouples 104 may be surrounded on both sides by printed conductors 102 and base plates 100.

A known integration of a thermoelectric module as a thermoelectric generator 200 in a system having a hot side 202 and a cold side 203 is outlined in FIG. 2. A heat exchanger 204 to which an insulator 206 is attached is located facing hot side 202. A conductor or a printed conductor 208 which may, for example, correspond to one of printed conductors 102 from FIG. 1 is located on the heat exchanger. A thermocouple of n-type 212 and a thermocouple of p-type 213 (each, for example, corresponding to one of thermocouples 104 and 106 from FIG. 1) are connected to printed conductor 208 via metallic areas 210. Metallic areas 214, conductors or printed conductors 216, insulator 218 and heat exchanger 220 correspond to components 210, 208, 206 and 204, as described above. Heat exchanger 220 faces cold side 203 of the system.

Normally, metals such as aluminum, stainless steel, titanium or copper are used as the material of heat exchangers 204 and 220. Heat exchangers 204 and 220 may be joined to the usually ceramic base plate or base support 206 or 218 (corresponding to support 100 from FIG. 1), for example, by welding, hard or soft soldering, cementing or friction-locked joining processes.

A robust use of thermoelectric generator 200, i.e., its reliable and long-lived operation, requires minimization of thermomechanical stresses occurring within generator 200. This problem arises in particular on the side of generator 200 facing hot side 202 and the metal-ceramic composite of layers 204 and 206 in that area. Stresses may result from the different thermal expansions of the used materials. Previous systems having the materials used heretofore also display very high thermal resistances. No systems have been available up to now that would make possible a simple adaptation of a general thermoelectric module or generator to different systems or processes or process environments. Conversely, a specific module has only been designed for a specific environment or a specific process and it cannot be used on or adapted to other process environments in a simple way without this adversely impacting its reliability and long life.

Due to high costs for the development and adaptation to specific process environments and/or correspondingly limited efficiency, thermoelectric generators have primarily been used only in the environment of aerospace engineering up to now. However, the provision of thermoelectric modules that could be more easily adapted to specific process environments would also open up, for example, vehicle construction as a field of application where such modules or generators would make possible more efficient utilization of waste heat from internal combustion engines or electric motors.

### BRIEF SUMMARY OF THE INVENTION

The present invention provides a thermoelectric module having the following components: Thermoelectric semiconductor elements, printed conductors made of metal for interconnecting the semiconductor elements, and at least one base support for the printed conductors. The base support includes a metal matrix composite.

In one specific embodiment of the thermoelectric module, a metal content of the metal matrix composite has a gradient between a side of the base support facing the printed conductors and a side of the base support facing away from the printed conductors.

For example, the metal matrix composite on the side of the base support facing the printed conductors may have 0 volume percent (vol %) metal. If the composite has, for example, a (porous) ceramic base substance, the porosity of which on the side of the base support facing the printed conductors is zero, an insulating ceramic layer is present there which assumes the insulator function. The metal-ceramic composite on the side of the base support facing away from the printed conductors has a metal content of 0 to 100%.

In other specific embodiments of the thermoelectric module according to the present invention, a bilateral gradient is present in the metal content which falls from maximum values on the side of the base support facing the printed conductors and the side of the base support facing away from the printed conductors to an intermediate metal content minimum. In this specific embodiment, at least one part of the printed conductors is implemented by the areas of the base support having maximum metal content values. The intermediate minimum should preferably be at a metal content of 0 vol %. The maximum metal content values on both sides of the base support may vary from one another. If the printed conductors are formed by the metallization of the metal matrix composite, a maximum value allowing an adequate current conduction and accordingly an interconnection of the thermocouples must be targeted. The maximum value on the side of the base support facing away from the printed conductors must be selected in such a way that thermal expansion and connection to the cold or hot side of the system is optimized.

In certain specific embodiments of the thermoelectric module according to the present invention, the base support includes an additional material having 0 vol % metal on the side of the metal matrix composite facing the printed conductors. This may in particular be 100 vol % of a ceramic material. For example, a ceramic having 100% volume filling may be applied, for example, by a sinter bonding method. In addition or alternatively, the base support may include an area having 100 vol % metal on the side of the metal matrix composite facing away from the printed conductors. A corresponding metal layer may be applied, for example, by recasting onto the metal matrix composite.

The present invention also provides a thermoelectric generator, which is designed in particular for a drive system in the transportation industry, for example, for an internal combustion engine or an electric motor of a vehicle. This generator has a thermoelectric module as described above.

Furthermore, a method for manufacturing a thermoelectric module as described above has the following steps: provision of a ceramic preform as a base support of the thermoelectric module; and infiltration of the ceramic preform with metal.

If an appropriate preform design having a porosity gradient is present, a gradient may be produced in the metal content of the later base support during infiltration.

Certain specific embodiments of the method include another upstream or downstream step of applying another material having 0 vol % metal. This may be in particular a ceramic material. This material is applied to one side of the preform. The material may be applied, for example, by a sinter bonding method before or after the metal infiltration.

In addition or alternatively, another upstream or downstream step of applying an area having 100 vol % metal to one (other) side of the preform may be provided. For example, a metal layer may be applied to the side of the preform facing away from the later printed conductors using a recasting method. This makes it possible to implement a heat exchanger having an environment of the later generator or possibly a connection to such a heat exchanger.

According to the present invention, the use of a metal matrix composite for thermoelectric modules or thermoelectric generators is also described.

The use of a metal matrix composite in a base support of a thermoelectric module makes it possible to adapt the coefficients of thermal expansion within the module in the presence of a simultaneously high thermal conductivity as a function of the specific process environment. The provision of a gradient in the metal content of the metal matrix composite makes it possible to implement the two functionalities of (1) insulating the printed conductors and (2) optimizing the connection to the hot or cold side of a system using the composite of the base support.

For example, the metal matrix composite on the side of the base support facing the printed conductors may have 0 vol % metal. If the composite has, for example, a (porous) ceramic base substance, the porosity of which on the side of the base support facing the printed conductors is zero, an insulating ceramic layer which assumes the insulator function is present there. On the side of the base support facing away from the printed conductors, the metal matrix composite has a metal content of 0 to 100%.

The suitable selection of the metal content allows a high thermal conductivity and simultaneously an optimized connection to the system in which the module or the generator is used while simultaneously ensuring the stability of the base support.

The described method for manufacturing a thermoelectric module makes it possible to use metal matrix composites as base plates or as base supports of thermoelectric modules, it being possible to ensure an integral connection between the insulator on the one side and the heat exchanger on the other side in a simple manner including optimal heat transfer and optimized coefficients of thermal expansion within the module and therefore the corresponding effects on the robustness of the module or generator.

A gradient in the metal content of the later base support ensures optimal connection to the environment of the module or generator on the one hand and the insulation of the printed conductors on the other hand. The method makes it possible to adapt the modules manufactured in this manner to specific process environments in a simple way.

### BRIEF DESCRIPTION OF THE DRAWINGS

FIG. 1 schematically shows the general structure of a thermoelectric module of the related art.

FIG. 2 schematically shows the general structure of a thermoelectric generator of the related art.

FIG. 3 schematically shows a first exemplary embodiment of a thermoelectric module/generator according to the present invention.

FIG. 4 shows a second exemplary embodiment of a thermoelectric module/generator according to the present invention.

FIG. 5 shows a third exemplary embodiment of a thermoelectric module/generator according to the present invention.

FIG. 6 shows an exemplary embodiment of a method according to the present invention for manufacturing a thermoelectric module.

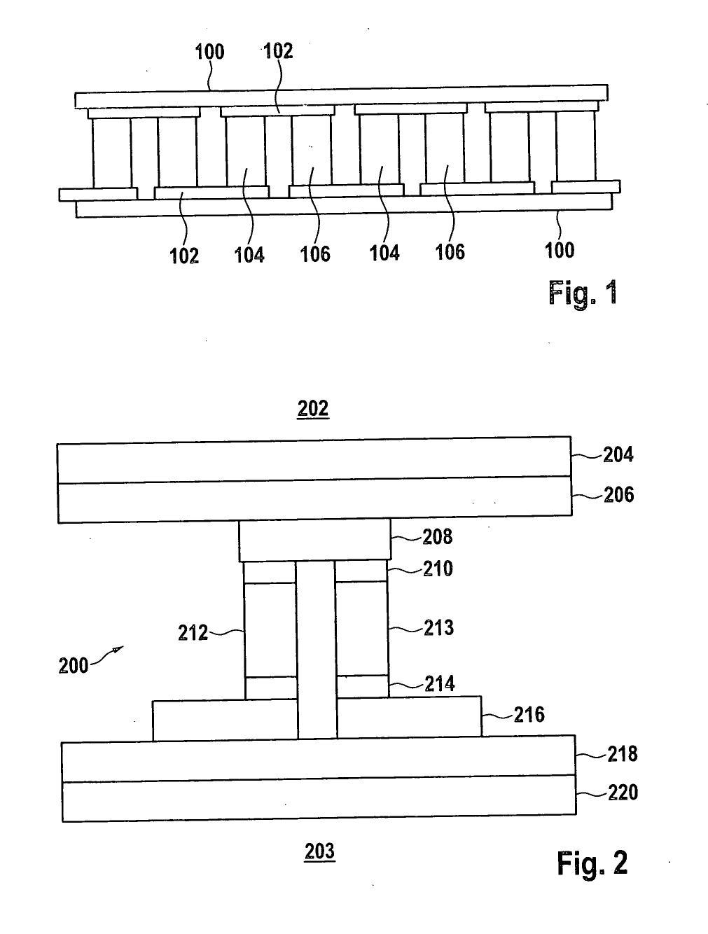

### DETAILED DESCRIPTION OF THE INVENTION

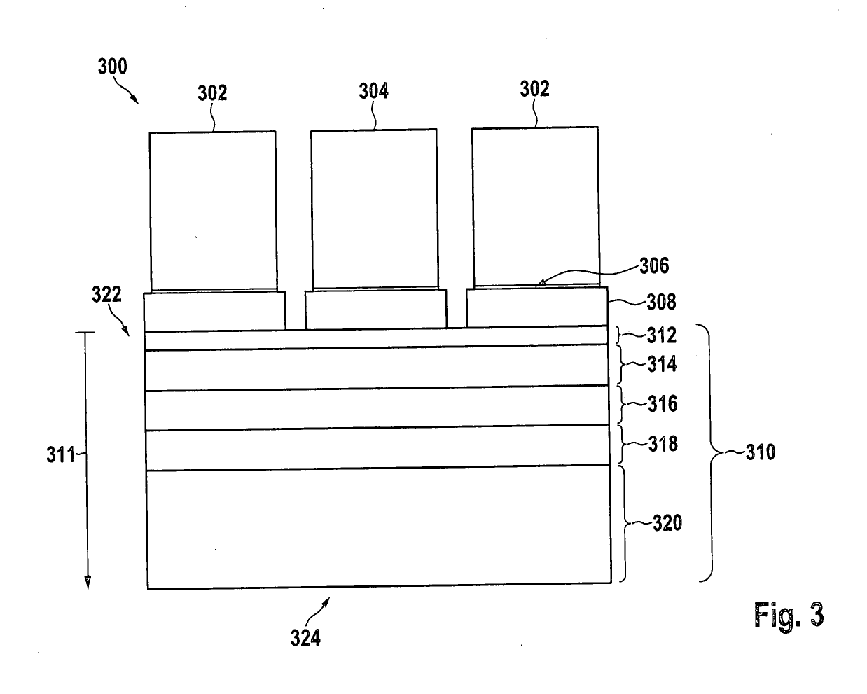

FIG. 3 shows an exemplary embodiment of a thermoelectric module 300 according to the present invention. Module 300 includes a plurality of p-type thermoelectric semiconductors 302 and n-type thermoelectric semiconductors 304, each of which is interconnected to one another in a suitable manner across a connecting layer 306 using printed conductors 308. Printed conductors 308 may, for example, be made of copper. Printed conductors 308 are located on a base support 310 which includes a graduated metal matrix composite (MMC). The graduation of the MMC is identified by an arrow 311 pointing in the direction of increasing metal content. In the example from FIG. 3, the graduation is discrete, i.e., base support 310 includes a total of five different layers denoted by reference numerals 312-320. The layers vary in the porosity of the preform from which base support 310 was manufactured or they vary correspondingly with respect to metal content. However, the graduation may also be designed to be continuous.

Specifically, layer 312, which lies on side 322 of base support 310 facing printed conductors 308 and is used as a support and insulator for printed conductors 308, may, for example, be made of up to 100% of a ceramic material, i.e., the original preform had 0% porosity in the area of layer 312. On the other hand, when module 300 is used as a generator, layer 320 lying on side 324 of base support 310 facing away from printed conductors 308 is itself used as a back plate, heat exchanger and/or for connecting to a heat exchanger which represents a hot side of a system, and is therefore made of 100% metal. Layers 314, 316 and 318 located between insulator layer 312 and heat exchanger or connection layer 320 have a graduated metal content of, for example, 25%, 50%, 75% metal content, the preform having by analogy, for example, a porosity of 25%, 50%, 75%.

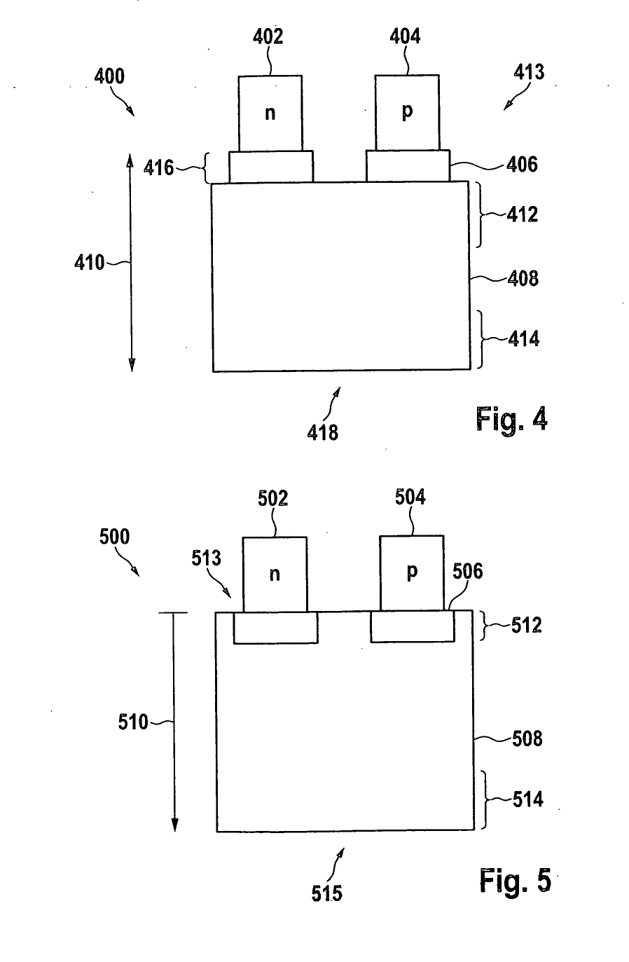

Another exemplary embodiment of a thermoelectric module 400 according to the present invention is shown in FIG. 4. Thermocouples of n-type 402 or p-type 404 are applied to conductor structures 406, which in this example are designed integrally with the base plate or base support 408. The integral design of base support 408 having conductor structures 406 simplifies in particular the manufacture of module 400. In contrast to exemplary embodiment 300 of FIG. 3 in which gradient 311 passes unilaterally, a bilateral gradient 410 is present in the case of base support 408 including conductor structures 406. This gradient has a minimum metal content in an area 412 on a side 413 facing printed conductors 406, while both an area 414 on side 418 facing away from conductor structures 406 and an area of printed conductors 406 each have a maximum metal content.

The metal content in areas 416 or 414 must be suitable for making (416) an interconnection of thermocouples 402, 404 or a thermal connection to the system in which module 400 is to be used (414). The metal content in areas 416 and/or 414 may thus vary from 100%.

Another exemplary embodiment of a thermoelectric module 500 according to the present invention is shown in FIG. 5. In this example, thermocouples of n-type 502 and p-type 504 are applied to conductor structures 506 which were introduced into recesses of a base plate 508. The introduction may be accomplished, for example using die casting, squeeze casting or gas pressure infiltration of metal. In the example of FIG. 5, a gradient 510 in the metal content of support 508 is unilateral and passes, for example, from 0% porosity of a ceramic preform of base plate 508 in an area 512 on side 513 of base support 508 facing printed conductors 506 to a maximum in the metal content in an area 514 on side 515 facing away from printed conductors 506 for connection to a system.

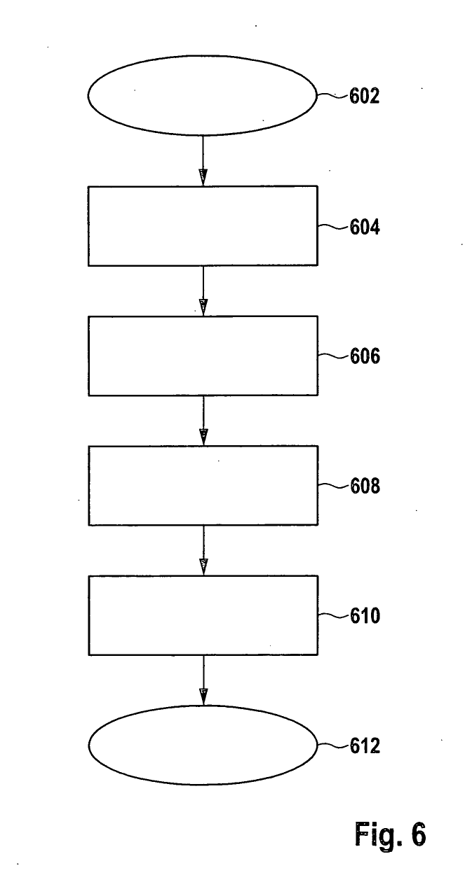

Based on the flow chart shown in FIG. 6, a method for manufacturing a thermoelectric module (602) is described. In step 604, a ceramic preform having a porosity gradient is provided as a base support of the later thermoelectric module. In step 606, the ceramic preform is infiltrated with metal. In this step, a gradient is accordingly produced in the metal content of the later base support. In step 608, another material having 0 volume percent metal is applied to one side of the preform. Alternatively, this material may already be represented using step 604. In step 610, an area having 100 volume percent metal is applied to another side of the preform. Alternatively, the area having 100 volume percent metal may be produced on the side facing away from the base support in step 606. The manufacturing process ends in step 612.

While gradient 311 in FIG. 3 is a graduated gradient, a bilateral gradient (410) or a unilateral gradient (510) may also pass without graduations, i.e., continuously from a minimum value to a maximum value of the metal content (or a porosity of a ceramic preform).

The metal matrix composite of support 310, 408 or 508 may be manufactured from porous ceramic preforms via metal infiltration, for example, using pressure support, for example, die casting, squeeze casting or gas pressure infiltration (step 606). This makes it possible to adapt the coefficient of thermal expansion (CTE) within the module to the system requirements, simultaneously ensuring high thermal conductivity. The ceramic preform may have a porosity gradient of, for example, 0 vol % in areas 312, 412, 512 to, for example, a maximum of 50 vol %, 75 vol %, in particular approximately 65 vol % in areas 318, 414, 514, sufficient mechanical stability still being ensured.

Areas 312 or 512 having 100 vol % ceramic or 0 vol % porosity may also be applied to the preform or the base support (step 608) using a sinter bonding method, optionally before or after a metal infiltration. Areas 320, 414 or 514 in which the porosity reaches 100 vol % or the metal content reaches 100 vol % may be applied to the base support, for example, by recasting of metal during the metal infiltration (step 610).

The present invention thus makes it possible to form an integral connection between insulator layer 312, 412 or 512 and the heat exchanger or connection side to system 320, 414 or 514. This ensures optimal thermal transfer with simultaneously minimal thermomechanical stresses within the module or generator.

Base support 310, 408 or 508 made from a metal matrix composite continues to offer an insulating base for circuit routing 308, 406 or 506 on the insulator or ceramic side, while a boundary surface having its coefficient of thermal expansion (CTE) adapted is available on the side having a high metal content 318/320, 414 and 514 for the metals of heat exchangers of the generator or system and/or the corresponding hot or cold side of the system.

Since the CTE in the module may be optimally adapted to the system requirement, the module designed according to the present invention offers significantly higher reliability with regard the thermomechanical loads compared to conventional TEMs. Simultaneously, the flexibility is increased with regard to the usable design and connection techniques and with regard to the installation space (required volume and required shaping) within the system when used as a thermoelectric generator. This is of significance for applications, for example, in the exhaust branch of an internal combustion engine.

According to the present invention, thermoelectric modules or generators made of graduated preform MMCs may be used economically at comparably low costs and increased energy efficiency for the efficient utilization of the waste heat of, for example, internal combustion engines or electric motors in the transportation industry (vehicle construction).

What is claimed is:

1. A thermoelectric module, comprising:
multiple thermoelectric semiconductor elements;
printed metal conductors for interconnecting the semiconductor elements; and
at least one base support for the printed conductors, wherein the base support includes a metal matrix composite.

2. The thermoelectric module as recited in claim 1, wherein a metal content of the metal matrix composite has a gradient between a side of the base support facing the printed conductors and a side of the base support facing away from the printed conductors.

3. The thermoelectric module as recited in claim 2, wherein the metal matrix composite has at least one of: (i) approximately 0 volume % metal content on the side of the base support facing the printed conductors; and (ii) 0 to 100 volume % metal content on the side of the base support facing away from the printed conductors.

4. The thermoelectric module as recited in claim 2, wherein the metal content of the metal matrix composite has a bilateral gradient which falls from maximum values on the side of the base support facing the printed conductors and on the side of the base support facing away from the printed conductors to an intermediate metal content minimum.

5. The thermoelectric module as recited in claim 2, wherein the base support has another material having 0 volume % metal and 100 volume % of a ceramic material, on the side of the metal matrix composite facing the printed conductors.

6. The thermoelectric module as recited in claim 2, wherein the base support includes an area having 100 volume % metal on the side of the metal matrix composite facing away from the printed conductors.

7. A method for manufacturing a thermoelectric module having multiple thermoelectric semiconductor elements, printed metal conductors for interconnecting the semiconductor elements, and at least one base support for the printed conductors, wherein the base support includes a metal matrix composite, the method comprising:
providing a ceramic preform as the base support;
infiltrating the ceramic preform with metal;
providing the printed metal conductors; and
providing the multiple thermoelectric semiconductor elements.

8. The method as recited in claim 7, wherein a gradient in the metal content of the base support is produced by a porosity gradient in the preform material during the infiltration.

9. The method as recited in claim 8, further comprising:
applying, on a first side of the preform, a ceramic material having 0 volume % metal.

10. The method as recited in claim 9, further comprising:
applying, on a second side of the preform, an area having 100 volume % metal.
